(19) United States
(12) Patent Application Publication
(10) Pub. No.: US 2012/0222888 A1
(43) Pub. Date: Sep. 6, 2012

(54) PCB WITH HEAT DISSIPATION STRUCTURE AND PROCESSING METHODS THEREOF

(75) Inventor: Tian Zhang, Guangdong (CN)

(73) Assignee: SHENZHEN CHINA STAR OPTOELECTRONIC tECHNOLOGY CO.,LTD, Shenzhen, Guangdong (CN)

(21) Appl. No.: 13/141,394

(22) PCT Filed: May 9, 2011
(86) PCT No.: PCT/CN2011/073826

§ 371 Date: Jun. 22, 2011

(30) Foreign Application Priority Data
Mar. 6, 2011 (CN) 201110063717.7

(51) Int. Cl. H05K 7/20; C04B 35/64

(52) U.S. Cl. 174/252; 156/89.16; 156/89.18; 156/89.19

(57) ABSTRACT

The invention relates to a printed circuit board (PCB) with a heat dissipating structure. The PCB comprises a conducting layer and a PCB carrier layer, wherein the PCB carrier layer is a porous heat conducting layer; heat conducting liquid or a solid-liquid phase change heat conducting material is injected into holes of the porous heat conducting layer; the conducting layer is arranged on a first surface of the porous heat conducting layer; and a second surface of the porous heat conducting layer is a contact interface with external media. In the invention, the carrier layer of the PCB is a porous heat conducting layer which is made of a porous material with high thermal conductivity, heat conducting liquid such as heat conducting ink or the solid-liquid phase change heat conducting material permeates into the holes of the porous heat conducting layer; when the PCB is heated, the heat conducting ink is separated out of the porous material because the expansion coefficient of the porous material is inconsistent with that of the heat conducting ink, and the separated heat conducting ink fills air gaps between the contact interface and the external medium in the contact interface of the PCB via capillary phenomenon, so that heat resistance between a light-emitting diode (LED) and the contact interface is reduced greatly and the thermal conductivity of the PCB is enhanced; moreover, the PCB has low cost, simple structure and easy installation.

### FIELD OF THE INVENTION

The invention relates to the technical field of printed circuit board (PCB), more particularly, to a PCB with a heat dissipating structure and a processing method thereof

### BACKGROUND OF THE INVENTION

In the application of the conventional light-emitting diode (LED) products, a plurality of LEDs need to be assembled on a single PCB generally. The PCB plays a role not only in bearing an LED module structure, but also in heat dissipating along with the increase of the output power of the LED so as to transfer heat produced by the LED outwards.

The conventional PCB for the LED comprises a support plate (namely, a carrier layer) and a conducting layer, wherein a heat conducting insulating layer is generally arranged between the conducting layer and the support plate; and the support plate is generally made of heat conducting metal with heat conducting and heat dissipating functions. However, the heat dissipating speed of the support plate is relatively slow, so that heat dissipation needs to be finished by means of other heat dissipating devices during the connection process of electrical appliances.

To solve the heat dissipating problem of the LED, the PCB is generally treated specially. For example, the PCB is provided with radiating fins or other heat dissipating components capable of conducting and dissipating heat, holes are drilled on FR4 PCB and copper is filled into the holes, or metal core PCB (MCPCB) is adopted, etc. However, when a light bar on the PCB is arranged on other heat dissipating component, the LED cannot dissipate heat easily through the PCB and the heat dissipating component because a plurality of grooves or gaps exist between the PCB and the contact interface of the heat dissipating component, a very thin air layer is formed, the air is a poor heat conductor and the heat resistance is high. To solve the problem of heat resistance on a heat transfer interface, the conventional methods include applying higher pressure to the contact interface of the PCB, or attaching a heat conducting adhesive tape or coating heat conducting adhesive, heat conducting estersil, heat conducting adhesive, a phase change material, etc. so as to reduce the heat transfer attenuation of air on the contact interface. However, the conventional methods have the defects of increase of working procedures, poor heat dissipating effect, complicated installation, higher cost and inconvenience for carrying and repairing.

### SUMMARY OF THE INVENTION

The main object of the invention is to provide a PCB with a heat dissipating structure, which has simple structure, low cost and good heat dissipating effect. Simultaneously, the invention also provides a method for processing the PCB with a heat dissipating structure.

In order to fulfill the above object, the invention provides a PCB with a heat dissipating structure, comprising a conducting layer and a PCB carrier layer, wherein the PCB carrier layer is a porous heat conducting layer; the porous heat conducting layer is made of a porous material which is obtained by mixing insulating and heat conducting material powder and an adhesive and pressing and sintering the mixture; heat conducting liquid is injected into holes of the porous heat conducting layer; the conducting layer is arranged on a first surface of the porous heat conducting layer; and a second surface of the porous heat conducting layer is a contact interface with an external medium.

Preferably, the insulating and heat conducting material powder at least comprises one of Al₂O₃, BeO, ALC and SiC powder.

Preferably, the adhesive at least comprises one of CaO—Al₂O₃—SiO₂ series solution, Mg—Al₂O₃—SiO₂ series solution and MnO—MgO—Al₂O₃—SiO₂ series solution.

Preferably, the heat conducting liquid is heat conducting ink.

The invention also provides a PCB with a heat dissipating structure, comprising a conducting layer and a PCB carrier layer, wherein the PCB carrier layer is a porous heat conducting layer; heat conducting liquid or a solid-liquid phase change heat conducting material is injected into holes of the porous heat conducting layer; the conducting layer is arranged on a first surface of the porous heat conducting layer; and a second surface of the porous heat conducting layer is a contact interface with an external medium.

Preferably, the porous heat conducting layer is made of a porous material which is obtained by mixing metal powder and an adhesive and pressing and sintering the mixture.

Preferably, an insulating layer is also comprised which is positioned between the conducting layer and the porous heat conducting layer, wherein the upper and lower surfaces of the insulating layer are bonded with the conducting layer and the porous heat conducting layer, respectively.

Preferably, the metal powder at least comprises one of aluminum, copper and tungsten.

Preferably, the porous heat conducting layer is made of a porous material which is obtained by mixing insulating and heat conducting material powder and an adhesive and pressing and sintering the mixture.

Preferably, the insulating and heat conducting material powder at least comprises one of Al₂O₃, BeO, ALC and SiC powder.

Preferably, the adhesive at least comprises one of CaO—Al₂O₃—SiO₂ series solution, Mg—Al₂O₃—SiO₂ series solution and MnO—MgO—Al₂O₃—SiO₂ series solution.

Preferably, the heat conducting liquid is heat conducting ink.

The invention also provides a method for processing the PCB with a heat dissipating structure, comprising:

mixing metal powder or insulating and heat conducting material powder and an adhesive, and performing mold pressing, mold injecting, extruding or rolling on the mixture so as to obtain a PCB substrate;

putting the PCB substrate into a high-temperature furnace so as to sinter the PCB substrate into a porous material;

shaping the porous material so as to form a porous heat conducting layer;

bonding a conducting layer on the first surface of the porous heat conducting layer and permeating heat conducting liquid or a solid-liquid phase change heat conducting material into the second surface of the porous heat conducting layer under vacuum or capillary action.

Preferably, before bonding the conducting layer on the first surface of the porous heat conducting layer, the method also comprises:

bonding an insulating layer on the first surface of the porous heat conducting layer.

Preferably, the metal powder at least comprises one of aluminum, copper and tungsten.

Preferably, the insulating heat conducting material powder at least comprises one of Al₂O₃, BeO, ALC and SiC powder.

Preferably, the adhesive at least comprises one of CaO—Al₂O₃—SiO₂ series solution, Mg—Al₂O₃—SiO₂ series solution and MnO—MgO—Al₂O₃—SiO₂ series solution.

Preferably, the heat conducting liquid is heat conducting ink.

The invention provides a PCB with a heat dissipating structure and a processing method thereof. The carrier layer of the PCB is a porous heat conducting layer which is made of a porous material with high thermal conductivity, heat conducting liquid such as heat conducting ink or a solid-liquid phase change heat conducting material permeates into the holes of the porous heat conducting layer; when the PCB is heated, the heat conducting ink is separated out of the porous material because the expansion coefficient of the porous material is inconsistent with that of the heat conducting ink and the separated heat conducting ink fills air gaps between the contact interface and the external medium in the contact interface of the PCB via capillary phenomenon, so that heat resistance between the LED and the contact interface is reduced greatly and the internal thermal conductivity of the PCB is enhanced greatly; moreover, the PCB has low cost, simple structure and easy installation.

### DESCRIPTION OF ATTACHED DRAWINGS

FIG. 1 is a sectional view of the first embodiment of the PCB with a heat dissipating structure in accordance with the invention;

FIG. 2 is a sectional view of the second embodiment of the PCB with a heat dissipating structure in accordance with the invention;

FIG. 3 is a flow chart of the method for processing the PCB with a heat dissipating structure shown in FIG. 1;

FIG. 4 is a flow chart of the method for processing the PCB with a heat dissipating structure shown in FIG. 2.

The realization, functional characteristics and advantages of the object of the invention will be further explained in combination with embodiments and with reference to attached drawings.

### DETAILED DESCRIPTION OF THE EMBODIMENTS

The general thought of the technical solution of the invention is: making the carrier layer of the PCB into a porous heat conducting layer with electric insulating and heat conducting functions or electric and heat conducting functions, and injecting heat conducting liquids such as heat conducting ink or a solid-liquid phase change heat conducting material into holes of the porous heat conducting layer, so as to reduce the heat resistance between the LED and the contact interface of the PCB and enhance the heat conducting effect of the PCB.

The technical solution for realizing the object of the invention is explained in detail in combination with attached drawings and embodiments in the following paragraphs. It should be understood that the embodiments described here are only used for explaining the invention but not limiting the patent scope of the invention.

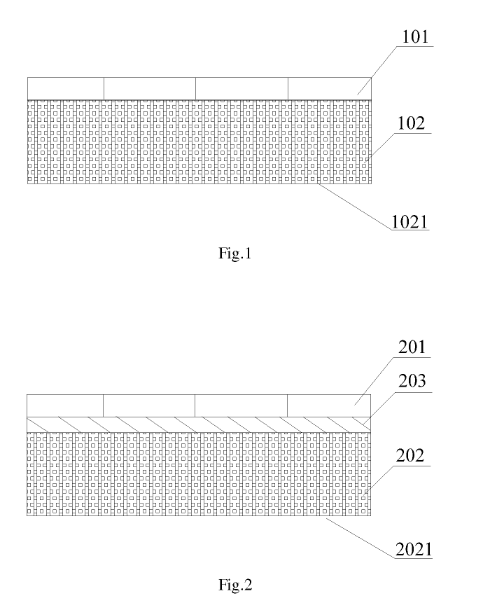

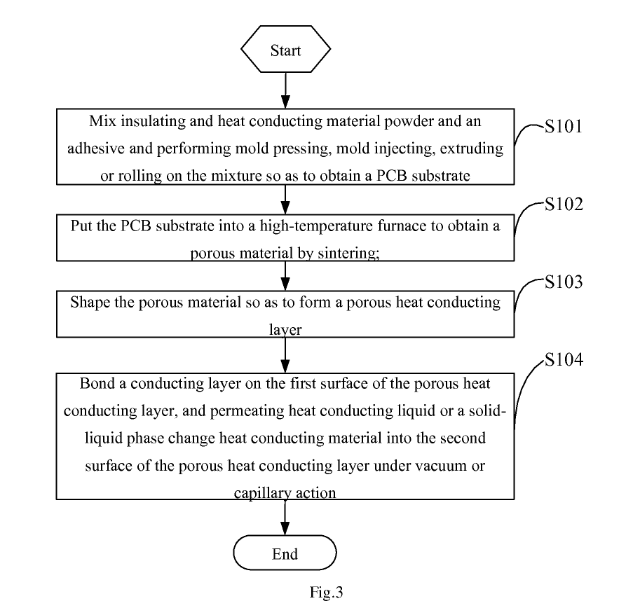

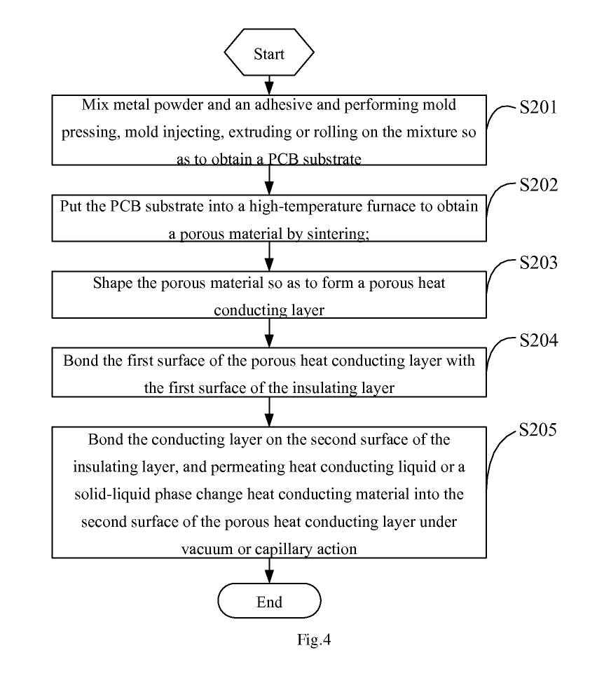

By referring to FIG. 1, the PCB with a heat dissipating structure provided by the first embodiment of the invention comprises a conducting layer 101 and a PCB carrier layer 102, wherein the PCB carrier layer 102 is a porous heat conducting layer which is made of a porous material with high thermal conductivity; and heat conducting liquids such as heat conducting ink or a solid-liquid phase change heat conducting material is injected into holes of the porous heat conducting layer.

The porous heat conducting layer comprises a first surface (not shown) and a second surface 1021 which is opposite to the first surface; the conducting layer 101 is arranged on and bonded with the first surface of the porous heat conducting layer and is provided with a plurality of LEDs. The second surface 1021 of the porous heat conducting layer is a contact interface which is contacted with an external medium.

1. A printed circuit board (PCB) with a heat dissipating structure, comprising a conducting layer and a PCB carrier layer, wherein the PCB carrier layer is a porous heat conducting layer; the porous heat conducting layer is made of a porous material which is obtained by mixing insulating and heat conducting material powders and an adhesive, and pressing and sintering the mixture; heat conducting liquid is injected into holes of the porous heat conducting layer; the conducting layer is arranged on a first surface of the porous heat conducting layer; and a second surface of the porous heat conducting layer is a contact interface with an external medium.

2-10. (canceled)

11. A PCB according to claim 1, wherein the insulating and heat conducting material powder at least comprises one of Al₂O₃, BeO, ALC and SiC powder.

12. A PCB according to claim 11, wherein the adhesive at least comprises one of CaO—Al₂O₃—SiO₂ series solution, Mg—Al₂O₃—SiO₂ series solution and MnO—MgO—Al₂O₃—SiO₂ series solution.

13. A PCB according to claims 12, wherein the heat conducting liquid is heat conducting ink.

14. A PCB with a heat dissipating structure, comprising a conducting layer and a PCB carrier layer, wherein the PCB carrier layer is a porous heat conducting layer; heat conducting liquid or a solid-liquid phase change heat conducting material is injected into holes of the porous heat conducting layer; the conducting layer is arranged on the first surface of the porous heat conducting layer; and the second surface of the porous heat conducting layer is a contact interface with an external medium.

15. A PCB according to claim 14, wherein the porous heat conducting layer is made of porous material which is obtained by mixing metal powder and an adhesive and pressing and sintering the mixture.

16. A PCB according to claim 15, also comprising an insulating layer which is positioned between the conducting layer and the porous heat conducting layer, wherein the upper and lower surfaces of the insulating layer are bonded with the conducting layer and the porous heat conducting layer respectively.

17. A PCB according to claim 16, wherein the metal powder at least comprises one of aluminum, copper and tungsten.

18. A PCB according to claim 14, wherein the porous heat conducting layer is made of a porous material which is obtained by mixing insulating and heat conducting material powder and an adhesive and pressing and sintering the mixture.

19. A PCB according to claim 18, wherein the insulating and heat conducting material powder at least comprises one of Al₂O₃, BeO, ALC and SiC powder.

20. A PCB according to claim 19, wherein the adhesive at least comprises one of CaO—Al₂O₃—SiO₂ series solution, Mg—Al₂O₃—SiO₂ series solution and MnO—MgO—Al₂O₃—SiO₂ series solution.

21. A PCB according to claim 20, wherein the heat conducting liquid is heat conducting ink.

22. A PCB according to claims 17, wherein the adhesive at least comprises one of CaO—Al₂O₃—SiO₂ series solution, Mg—Al₂O₃—SiO₂ series solution and MnO—MgO—Al₂O₃—SiO₂ series solution.

23. A PCB according to claims 22, wherein the heat conducting liquid is heat conducting ink.

24. A method for processing the PCB with a heat dissipating structure, comprising:
mixing metal powder or insulating and heat conducting material powder and an adhesive and performing mold pressing, mold injecting, extruding or rolling on the mixture so as to obtain a PCB substrate;
putting the PCB substrate into a high-temperature furnace so as to sinter the PCB substrate into a porous material;
shaping the porous material so as to form a porous heat conducting layer;
bonding a conducting layer on the first surface of the porous heat conducting layer and permeating heat conducting liquid or a solid-liquid phase change heat conducting material into the second surface of the porous heat conducting layer under vacuum or capillary action.

25. A method according to claim 24, before the bonding of the conducting layer on the first surface of the porous heat conducting layer, also comprising:
bonding an insulating layer on the first surface of the porous heat conducting layer.

26. A method according to claim 24, wherein the metal powder at least comprises one of aluminum, copper and tungsten.

27. A method according to claim 24, wherein the insulating and heat conducting material powder at least comprises one of Al₂O₃, BeO, ALC and SiC powder.

28. A method according to claim 24, wherein the adhesive at least comprises one of CaO—Al₂O₃—SiO₂ series solution, Mg—Al₂O₃—SiO₂ series solution and MnO—MgO—Al₂O₃—SiO₂ series solution.

29. A PCB according to claims 24, wherein the heat conducting liquid is heat conducting ink.
